(19) United States
(12) Patent Application Publication
(10) Pub. No.: US 2004/0262148 A1
(43) Pub. Date: Dec. 30, 2004

(54) Sputter cathode assembly for uniform film deposition

(76) Inventors: Yuanda Randy Cheng, Phoenix, AZ (US); Jianzhong Shi, Singapore (SG); Wah Meng Soh, Singapore (SG); Chee Yong Tan, Singapore (SG); Goeh Wee Chor, Singapore (SG); Ping Xu, Singapore (SG); Yeong Wah Chua, Singapore (SG); Chinsoon Koh, Singapore (SG); Stephen Hiroshi Sawasaki, Scotts Valley, CA (US)

Correspondence Address: Raghunath S. Minisandram, Seagate Technology LLC, 920 Disc Drive, SV15B1, Scotts Valley, CA, 95066, US

(21) Appl. No.: 10/876,199

(22) Filed: Jun. 23, 2004

Related U.S. Application Data
(60) Provisional application No. 60/482,189, filed on Jun. 23, 2003.

(51) Int. Cl. C23C 14/00; C23C 14/32; C25B 9/00

(52) U.S. Cl. 204/192.1; 204/192.2; 204/192.12; 204/298.16

(57) ABSTRACT

A system for sputtering uniformly thick films on a substrate is disclosed. The system includes a magnetron-sputtering cathode in a vacuum chamber, a gas inlet which injects processing gas at one end of the chamber, and a pump that pumps the processing gas from the other end of the chamber causing the process gas to flow across the substrate during processing. The magnetron-sputtering cathode includes a magnet array that is substantially circular. The magnets on the magnet array are positioned such that the gap between the magnets is smaller on the top of the array near the gas inlet than on the bottom of the array near the pump. The distribution of magnets creates a magnetic flux profile that results in more of the target being sputtered near the top of the cathode creating a thicker film at the top of the substrate. This thickness non-uniformity is opposite to the uniformity created by injecting gas from the top of the substrate and pumping that gas from the bottom of the substrate so that when the two are combined a uniformly thick layer results on the substrate.

This application claims priority from U.S. provisional application Ser. No. 60/482,189 filed on Jun. 23, 2003.

### BACKGROUND OF THE INVENTION

1. Field of the Invention

The present invention relates generally to manufacturing processes involving the thin film coating of substrates. More particularly, the present invention relates to cathodes used for sputtering thin films.

2. Description of the Related Art

Various manufacturing processes involve the deposition or coating of multiple layers of materials on a substrate by sputtering. A basic sputtering operation includes bombarding a target material with ions to release atoms from the surface of the target. The released atoms are directed towards the substrate so that they become deposited on the surface of the substrate. To build up the desired multiple layers of different materials, the sputtering operation is repeated with a previously coated substrate, using targets of different materials in each sputtering operation.

When depositing films on a substrate it is important to have uniformity throughout the entire substrate. For example if a film is deposited onto a substrate that is circular and 3 inches in diameter then the thin film deposition apparatus and method used must be capable of depositing uniform films throughout the entire 3 inch diameter. Uniformity includes thickness uniformity, crystallographic uniformity, compositional uniformity, etc. The larger the substrate area there is the harder it becomes to control uniformity throughout the entire substrate. Often times the uniformity-requirements can be very stringent such as thickness requirements that have tolerances as tight as several angstroms meaning that the thickness of the deposited film cannot vary by more than several angstroms across the substrate.

Magnetic media used in conventional disc drives is an example of a mutli-layer structure with stringent requirements for film uniformity. Thickness uniformity requirements for magnetic media are very stringent because the entire disk is used to record information. If all the deposited films are not substantially the same engineered thickness at all locations of the disk then the entire disk is unusable because one must be able to read and write information to the entire disk rather than just a portion of the disk. Magnetic media is used in conventional disc drives that are used to magnetically record, store and retrieve digital data. Data is recorded to and retrieved from one or more discs that are rotated at more than one thousand revolutions per minute (rpm) by a motor. The data is recorded and retrieved from the discs by an array of vertically aligned read/write head assemblies, which are controllably moved from data track to data track by an actuator assembly.

The three major components making up a conventional hard disc drive are magnetic media, read/write head assemblies and motors. Magnetic media, which is used as a medium to magnetically store digital data, typically includes a layered structure, of which at least one of the layers is made of a magnetic material, such as CoCrPtB, having high coercivity and high remnant moment. The read/write head assemblies typically include a read sensor and a writing coil carried on an air bearing slider attached to an actuator. This slider acts in a cooperative hydrodynamic relationship with a thin layer of air dragged along by the spinning discs to fly the head assembly in a closely spaced relationship to the disc surface. The actuator is used to move the heads from track to track and is of the type usually referred to as a rotary voice coil actuator. A typical rotary voice coil actuator consists of a pivot shaft fixedly attached to the disc drive housing closely adjacent to the outer diameter of the discs. Motors, which are used to spin the magnetic media at rates higher than 10,000 revolutions per minute (rpm), typically include brushless direct current (DC) motors. The structure of disc drives is well known.

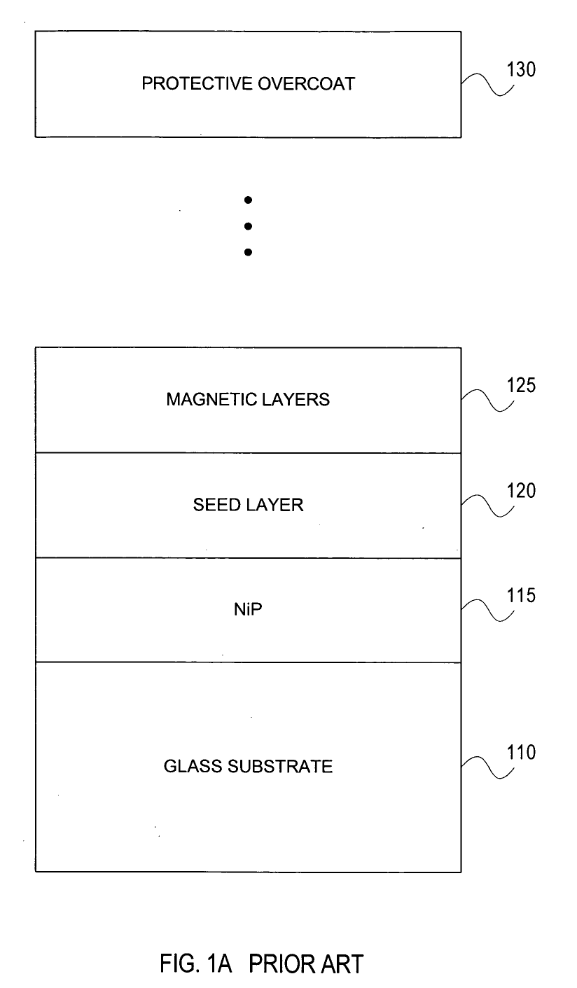

FIG. 1A illustrates a conventional magnetic media structure comprising a substrate 110, a nickel-phosphorous (NiP) layer 115, a seed layer 120, a magnetic layer 125 and a protective layer 130. The substrate 110 is typically made of aluminum or high quality glass having few defects. The nickel-phosphorous (NiP) layer 115 is an amorphous layer that is usually electrolessly plated or sputtered onto the substrate 110. The NiP layer is used to enhance both the mechanical performance and magnetic properties of the disk. The NiP layer enhances the mechanical properties of the disk by providing a hard surface on which to texture. The magnetic properties are enhanced by providing a textured surface that improves the magnetic properties including the orientation ratio (OR).

Seed layer 120 is typically a thin film made of chromium that is deposited onto the NiP layer 115 and forms the foundation for structures that are deposited on top of it. Magnetic layer 125, which is deposited on top of seed layer 120, typically includes a stack of several magnetic and non-magnetic layers. The magnetic layers are typically made out of magnetic alloys containing cobalt (Co), platinum (Pt) and chromium (Cr), whereas the non-magnetic layers are typically made out of metallic non-magnetic materials. Finally, protective overcoat 130 is a thin film typically made of carbon and hydrogen, which is deposited on top of the magnetic layers 1.25 using conventional thin film deposition techniques.

Increases in areal density growth have lead to the introduction of complex film structures, which are composed of many ultra-thin layers of magnetic and non-magnetic materials. In order to support the required magnetic recording densities, the physical thickness of each of the layers in the multi-layer structure have to be uniform in both the circumferential and radial directions. Any non-uniformity of the thin film layers can cause degradation in the read-write performance of the finished magnetic media, which in turn can affect the product yields at both media component level and at the finished drive product level.

Nevertheless, most thin film deposition sputtering tools utilize designs having gas inlets at one end of the vacuum chamber and pumping at the other end causing a pressure gradient across the substrate, ultimately resulting in films having non-uniform thickness. Typically the thickness profile of the film in such a system is that the film is thinner at the end where the gas is introduced into the vacuum chamber and thicker at the end where the gas is being pumped. The prior art original plasma magnetron-cathode, which is used to sputter target material and is shown in FIG. 1B, does not correct or account for this non-uniformity. The magnetic media described with reference to FIG. 1A is typically made by sputter depositing the different layers while the substrate is maintained in an upward position with gas being let in at the top of the substrate and pumped out from the bottom. In addition, the vacuum pump beneath the sputter cathode is typically mounted on the bottom of the cathode, resulting in more pronounced differences in thickness and magnetic properties across the disk from top-to-bottom. The non-uniformity across the disk can be as high as 10%, and is worse at the outer diameter of the disks.

Therefore what is needed is a system for depositing uniformly thin films on substrates using sputtering tools that inject gas from the top of a chamber, where one end of the substrate is located, and pump gas from the bottom of the chamber, where the other end of the substrate is located.

### SUMMARY OF THE INVENTION

The invention provides a system for depositing uniform films on a substrate using sputtering tools that inject gas from the top of a chamber, where one end of the substrate is located, and pump gas from the bottom of the chamber, where the other end of the substrate is located.

The system includes a magnetron-sputtering cathode comprising a first plurality of magnets positioned and spaced apart in a substantially outer circular pattern such that gaps are formed between each magnet and a second plurality of magnets positioned and spaced apart in a substantially inner circular pattern, wherein said inner circular pattern is located inside of said outer circular pattern. Additionally, and in another aspect of the invention, the substantially outer circular pattern of the magnetron-sputtering cathode further includes a top pattern and a bottom pattern that can have gaps between the magnets in the top pattern that are of a different size than the gaps between the magnets in the bottom pattern. In one embodiment, the bottom pattern gaps are larger than the top pattern gaps. The outer circular pattern and inner circular pattern of the magnetron-sputtering cathode can be concentrically located with respect to each other.

Another embodiment of the invention includes a sputtering apparatus comprising a chamber, a gas inlet for supplying gas used in sputtering, a vacuum pump connected with the chamber, a magnetron-sputtering cathode positioned within the chamber, wherein the magnetron-sputtering cathode further comprises a first plurality of magnets positioned and spaced apart in a substantially outer circular pattern such that gaps are formed between each magnet, wherein the substantially outer circular pattern further includes a top pattern and a bottom pattern, and a second plurality of magnets positioned and spaced apart in a substantially inner circular pattern, wherein said inner circular pattern is located inside of said outer circular pattern. The magnetron-sputtering cathode of the apparatus can be positioned so that the bottom pattern is oriented towards the vacuum pump allowing gas to flow in front of the bottom pattern before entering the vacuum pump. Additionally the size of the gaps in the top pattern can be different size than the gaps in the bottom pattern or preferably the gap of the bottom pattern can be larger than the gap of the top pattern.

In another embodiment of the invention the sputtering apparatus can further include a second magnetron-sputtering cathode substantially similar to the magnetron-sputtering cathode previously disclosed. The second magnetron-sputtering cathode can be positioned opposite to and symmetric to the other magnetron-sputtering cathode so that both sides of a substrate can be simultaneously sputtered.

Another embodiment of the invention includes a method of producing uniform magnetic films, comprising providing a substrate into a sputtering apparatus, injecting a gas to enter into the sputtering apparatus, passing the gas over the substrate and over a magnetron-sputtering cathode and pumping out the gas into a vacuum pump disposed within said sputtering apparatus. The magnetron-sputtering cathode further comprises a first plurality of magnets positioned and spaced apart in a substantially outer circular pattern such that gaps are formed between each magnet. The substantially outer circular pattern further includes a top pattern and a bottom pattern. The magnetron-sputtering cathode also further comprises a second plurality of magnets positioned and spaced apart in a substantially inner circular pattern. The inner circular pattern is located inside of the outer circular pattern.

In other embodiments of the invention the substrate used can be substantially circular and the gas used can be a noble gas such as argon or xenon. If a reactive process is used then the gas can be a reactive gas such as a mixture of argon and oxygen or argon nitrogen. Additionally, the substantially outer circular pattern can further include a top pattern and a bottom pattern wherein the gaps between the magnets making up the top pattern and bottom pattern are different. More specifically the gaps between the magnets in the bottom pattern, which is oriented towards the vacuum pump, are larger than the gaps between the magnets in the top pattern, which is oriented towards the gas inlet.

In another embodiment, both sides of a substrate are coated simultaneously by using a second cathode substantially similar to the first cathode and positioned oppositely and symmetrically to the first cathode.

A disc drive for recording and retrieving data using the magnetic recording medium made in accordance with this invention is also disclosed in this invention.

### BRIEF DESCRIPTION OF THE INVENTION

FIG. 1A is a block diagram showing a prior art conventional magnetic media structure.

FIG. 1B is an illustration showing the prior art original plasma magnetron-cathode used in sputtering apparatuses.

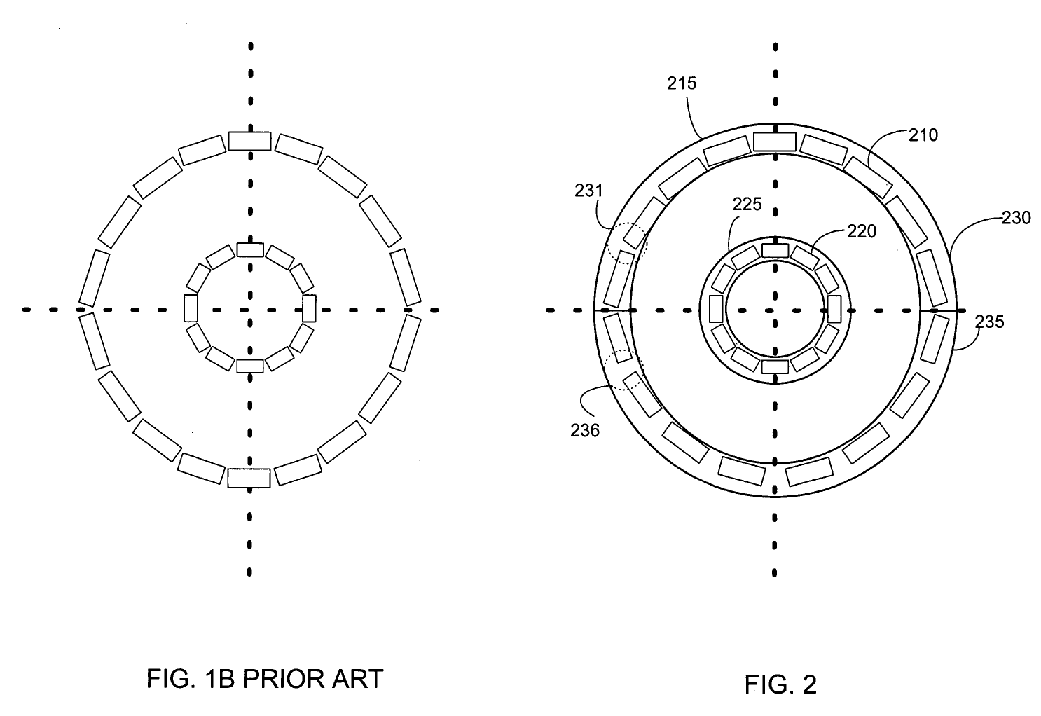

FIG. 2 is an illustration showing the magnetron-sputtering cathode used to improve film uniformity in accordance with one embodiment of the invention.

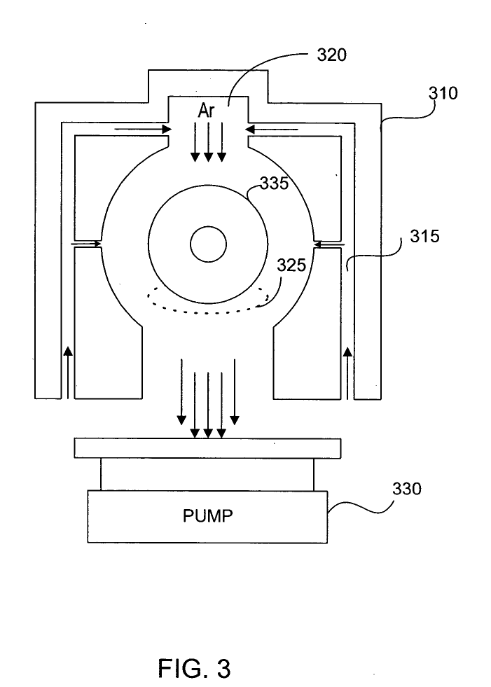

FIG. 3 is an illustration showing the magnetron-sputtering cathode used to improve film uniformity of FIG. 2 incorporated into a thin film sputter deposition apparatus.

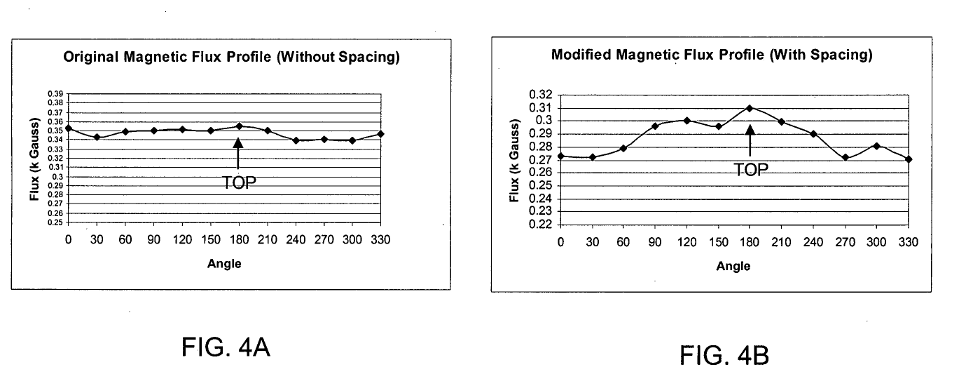

FIG. 4A-4B are graphs showing and comparing the magnetic flux profile in Kilo-Gauss as a function of angle around the magnetron-sputtering cathode for the prior art original magnetron-sputtering cathode and the magnetron-sputtering cathode of FIG. 2, respectively.

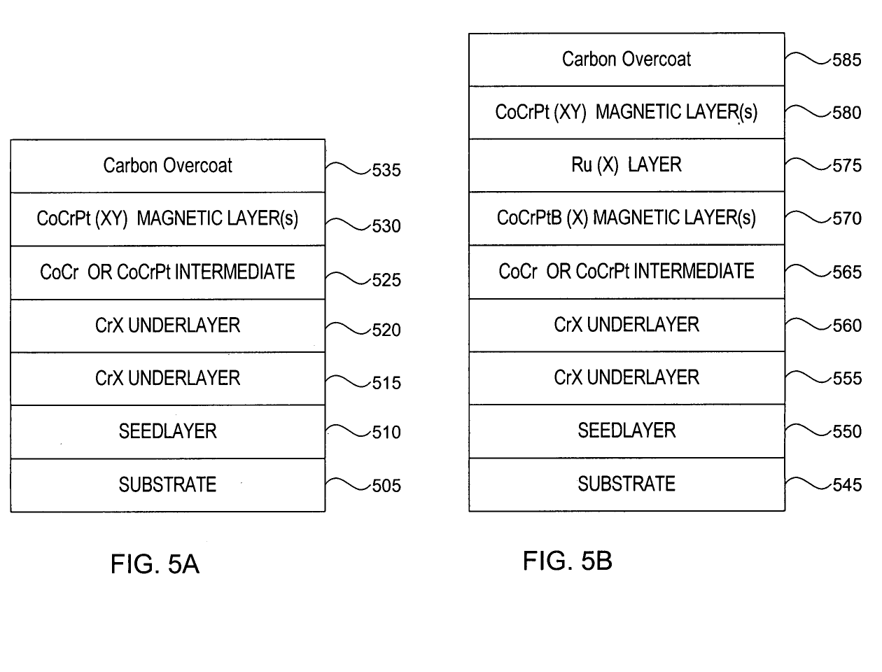

FIG. 5A-5B are examples of two magnetic media structures made with the magnetron-sputtering cathode of FIG. 2, in accordance with one embodiment of the invention.

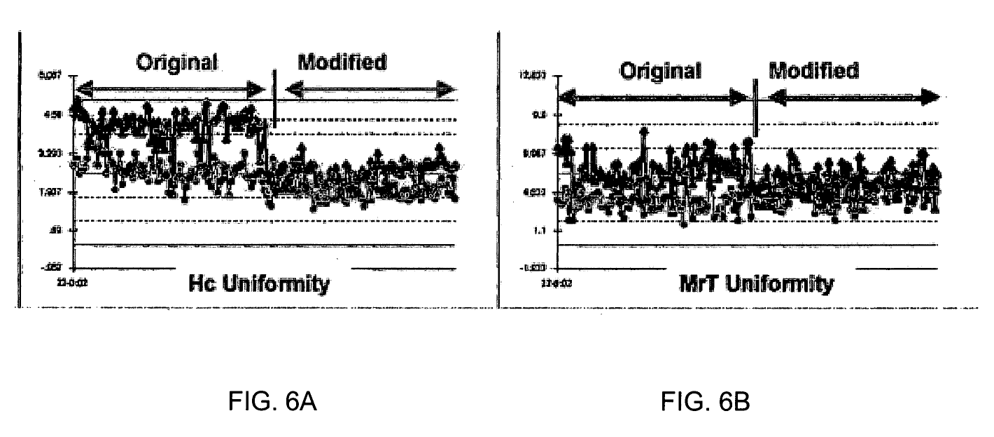

FIG. 6A is a graph showing and comparing the coercivity (Hc) uniformity of a magnetic media structure made with the original plasma magnetron-sputtering cathodes and made with the magnetron-sputtering cathode of FIG. 2.

FIG. 6B is a graph showing and comparing the (magnetic remnant)×(thickness) (MrT) uniformity of a magnetic media structure made with the original plasma magnetron-sputtering cathodes and made with the magnetron-sputtering cathode of FIG. 2.

### DETAILED DESCRIPTION OF THE PREFERRED EMBODIMENTS

The invention provides a system and method for making a multilayer thin film structure using sputtering techniques. The system provides a way to deposit multilayers of uniform thickness in a high throughput sputtering tool that injects processing gas from a first end of a vacuum chamber while pumping out the processing gas at a second end of the vacuum chamber. The invention comprises of modifying the current sputter cathode to compensate for different sputter rates between a first end of the chamber, where gas is injected into the chamber, and a second end of the chamber, where gas is pumped out of the chamber. The difference in sputter rates between the first end of the chamber and the second end of the chamber result in film thicknesses on a substrate that are thinner at the first end where gas is injected and thinner at the second end where gas is pumped out of the chamber.

The magnetron-sputtering cathode used in this invention is a modified plasma magnetron-sputtering cathode containing permanent magnets and a shunt made of soft magnetic material. On each side of the original plasma magnetron-sputtering cathode the magnets are evenly distributed at both inner and outer circles for the original design as illustrated in FIG. 1B. The strength and orientation of the magnetic flux define the sputter rate and erosion area on the target. In order to compensate for the thin film thickness at the first end of the substrate where gas is injected, the inventive magnetron-sputtering cathode is modified to have closely spaced magnets on the first end, which is near the first end of the chamber where gas is injected, and more spaced-out magnets at the second end, which is near the second end of the chamber where gas is pumped out of the chamber, as illustrated in FIG. 2. FIG. 1B and FIG. 2 have been positioned side-by-side so that the difference is clearly seen. The improvement in the magnetic flux profile is illustrated in FIG. 3A and FIG. 3B, which shows a side-by-side comparison of the magnetic flux profile for the prior art original plasma magnetron-sputtering cathode and the magnetron-sputtering cathode of FIG. 2, respectively.

FIG. 2 is an illustration showing the magnetron-sputtering cathode used to improve film uniformity including a first set of magnets 210 positioned and spaced apart in a substantially circular outer pattern 215, a second set of magnets 220 positioned and spaced apart in a substantially circular inner pattern 225. The substantially circular outer pattern 215 is made of a top pattern 230 having a first gap 231 between magnets and a bottom pattern 235 having a second gap 236 between magnets. First gap 231 and second gap 236 are different size. More specifically, first gap 231 can be smaller than second gap 236. Outer pattern 215 and inner pattern 225 are positioned so that inner pattern 225 is located inside of outer pattern 215 and preferably outer pattern 215 and inner pattern 225 are concentric with other. The term gap is intended to include gaps of zero length as well as gaps of non-zero length. Therefore, in this disclosure, two magnets separated by a length of zero is intended to mean two magnets that are in contact. Similarly two magnets separated by a gap of 1 centimeter is intended to mean two magnets separated by a length of 1 centimeter. Additionally, a description stating that gaps of at least two different sizes are formed between each magnet means that one of the sizes can be zero and the magnets are in contact.

Magnets 210 are positioned to make up top pattern 230 and bottom pattern 235 as well as outer pattern 215 and inner pattern 225. First set of magnets 210 and second set of magnets 220 are preferably permanent magnets such as SmCo, NdFeB or other known permanent magnet materials. The magnets 210 are all of substantially similar strength. Magnets 210 can be any shape such as rectangular, circular, cylindrical, etc, but preferably are rectangular. The magnets 210 are assembled together to form both the top pattern 230 and the bottom pattern 235. The magnets 210 making up top pattern 230 are positioned so that there is a first gap 231 between each of the magnets. Similarly, the magnets 210 making up bottom pattern 235 are positioned so that there is a second gap 236 between each of the magnets. Since first gap 231 is smaller than second gap 236, there are fewer magnets in top pattern 230 than in bottom pattern 235. FIG. 2 shows that top pattern 230 has nine magnets whereas bottom pattern 235 has 8 magnets. A comparison with the prior art cathode of FIG. 1B shows that both the top half and second half of the circular pattern each have nine magnets. Similarly, the second set of magnets 220 which make up the inner pattern 225 are all made of substantially the same strength and can be any shape as are first set of magnets 210. However, first set of magnets and second set of magnets are positioned so that the magnetic field generated by these sets of magnets penetrate beyond the surface of the target material so that electrons can be trapped creating a plasma for sputtering. One way of accomplishing this is by positioning the first set of magnets 210 so that their polarity is reversed in reference to the second set of magnets 220. Such a configuration causes the magnetic field leaving the first set of magnets to enter the second set of magnets creating a closed magnetic field loop.

The weaker magnetic field produced by the fewer magnets on the bottom pattern 235 will reduce the sputter rate of the target in this region and therefore decrease the thickness of the film deposited onto a substrate in the region of the substrate near the bottom pattern 235. Additionally, the gas flow dynamics increases the sputter rate of the target in the region near the bottom pattern 235 because the gas flow in the sputtering tool flows from an inlet near the top pattern 230 to the pump located near the bottom pattern 235. The gas flow dynamics produces a film that is thicker near the bottom pattern 235 whereas the magnetron-sputtering cathode produces a thinner film near the bottom pattern 235. Therefore, the magnetron-sputtering cathode undoes the non-uniformity created by the gas flow. The improvement in thickness uniformity is reflected in the improved magnetic uniformity of the coercivity and MrT, as further discussed with reference to FIG. 6A-6B.

FIG. 3 is an illustration showing the magnetron-sputtering cathode of FIG. 2 incorporated into a thin film sputter deposition apparatus including a vacuum chamber 310, a gas line 315, a gas inlet 320, secondary gas inlets 322, gas flow (arrows) 325, a pump 330, a substrate 335, and a region of thicker film 340. Vacuum chamber 310 is a chamber used for processing thin films and is strong enough to support vacuum pressures as low as 10⁻⁹ torr and is clean enough to be used to make semi-conductor grade thin films. Vacuum chamber 310 can be made of a sturdy metal such as stainless steel. Gas line 315 is a gas supply line that supplies processing gas to the vacuum chamber and runs from outside of the vacuum chamber into the gas inlet 320 for processing substrates. Gas inlet 320 is located at the top end of the vacuum chamber and injects gas into the chamber. Additionally there are two smaller secondary gas inlets 322 which permit a small amount of gas to flow into the vacuum chamber. The process gas flows in the direction of the gas flow arrows 325 from the gas inlet 320 to the pump 325. The pump 325 is a vacuum pump capable of pumping gas at low pressures and can be a turbo molecular pump, cryogenic pump, dry mechanical pump, diffusion pump or other low-pressure pump. The substrate 335 can be metallic or glass as is further discussed with reference to FIGS. 5A and 5B below. The region of thicker film 340 is the region on the substrate where the deposited film will be thicker because of the gas flow dynamics of the sputtering system.

FIG. 4A-4B are graphs showing and comparing the magnetic flux profile in Kilo-Gauss (kGauss) as a function of angle around the magnetron-sputtering cathode for the prior art original plasma magnetron-sputtering cathode and the modified magnetron-sputtering cathode of FIG. 2, respectively. FIG. 4A shows that magnetic flux profile around the circular original plasma magnetron-sputtering cathode from 0 degrees to 360 degrees is approximately 0.35±01 kGauss. In contrast FIG. 4B shows the magnetic flux profile around the circular modified magnetron-sputtering cathode of FIG. 2 from 0 degrees to 360 degrees which shows a peak in the magnetic flux at approximately 180 degrees which corresponds to the top of the magnetron-sputtering cathode or the portion of the magnetron-sputtering cathode nearest the gas inlet. This increase in magnetic flux near the top of the cathode results in more of the target being sputtered near the top of the cathode, which creates a thicker film at the top of the substrate.

FIG. 5A-5B are examples of two magnetic media structures made with the magnetron-sputtering cathode of FIG. 2, in accordance with one embodiment of the invention. FIG. 5A is a longitudinal recording media with layers comprising platinum (Pt) whereas FIG. 5B is an anti-ferromagnetically coupled (AFC) recording media comprising ruthenium (Ru) and platinum (Pt) containing layers.

FIG. 5A is a magnetic media structure, made using the magnetron-sputtering cathode of FIG. 2, including a substrate 505, a seedlayer 510, a first underlayer 515, a second underlayer 520, an intermediate layer 525, a magnetic layer 530, and a carbon overcoat 535. The substrate 505 can be made of aluminum, nickel-phosphorous coated aluminum, glass, ceramic based or other materials known in the art. The seedlayer 510 is optional and is used for enhancing the magnetic properties of the media. The first underlayer 515 and second underlayer 520 comprises of Cr or Cr-based alloys such as CrW, CrMo, CrTa or CrV. Depending on the application one of the underlayers can be optional. The intermediate layer 525 comprises CoCr, or CoCrPt or other CoCr-based alloys. The magnetic layer 530 comprises of either one or more layers of CoCrPt based alloys such as CoCrPtB, or CoCrPtTaB. The carbon overcoat 535 on top of the magnetic layer can be pure carbon, diamond-like-carbon (DLC), or nitrogenated carbon.

Similarly, FIG. 5B is a magnetic media structure, made using the magnetron-sputtering cathode of FIG. 2, including a substrate 545, a seedlayer 550, a first underlayer 555, a second underlayer 560, an intermediate layer 565, a first magnetic layer 570, a coupling layer 575, a second magnetic layer 580, and a carbon overcoat 585. The substrate 545 can be made of aluminum, nickel-phosphorous coated aluminum, glass, ceramic based or other materials known in the art. The seedlayer 550 optional and is used for enhancing the magnetic properties of the media. The first underlayer 555 and second underlayer 560 comprises of Cr or Cr-based alloys such as CrW, CrMo, CrTa or CrV. Depending on the application one of the underlayers can be optional. The intermediate layer 565 comprises CoCr, or CoCrPt or other CoCr-based alloys. The first magnetic layer 570 comprises of either one or more layers of CoCrPt based alloys such as CoCrPtB, or CoCrPtTaB. The coupling layer 575 can consist of one, two or more layers made of Ru or RuCr that is sputtered between the first magnetic layer 570 and the second magnetic layer 580. The thickness of the coupling layer ranges from 1 to 50 angstroms. The second magnetic layer 580 can be made of he same material as the first magnetic layer 570 or other magnetic material. The carbon overcoat 585 on top of the second magnetic layer 580 can be pure carbon, diamond-like-carbon (DLC), or nitrogenated carbon.

FIG. 6A is a graph showing and comparing the coercivity (Hc) at various points around a magnetic media structure made with the original plasma magnetron-sputtering cathodes and made with the magnetron-sputtering cathode of FIG. 2. The Hc uniformity is determined by looking at the spread in the data. The data range labeled “Original” is Hc data for a magnetic media structure made with the prior art original plasma magnetron-sputtering cathode. Similarly, the data range labeled “Modified” is Hc data for a magnetic media structure made with the new magnetron-sputtering cathodes of FIG. 2. The data of FIG. 6A shows that the spread in Hc values decreases significantly when the “Original” cathodes are changed out for the “Modified” cathodes. This improved Hc uniformity is a direct result of the improved magnetron-sputtering cathode having magnetic flux shown in FIG. 4B, which compensates for non-uniformities resulting from gas flowing from the top of the substrate to the bottom of the substrate.

FIG. 6B is a graph showing and comparing the (magnetic remnant)×(thickness) (MrT) at various points around a magnetic media structure made with the original plasma magnetron-sputtering cathodes and made with the magnetron-sputtering cathode of FIG. 2. The MrT uniformity is determined by looking at the spread in the data. The data range labeled “Original” is MrT data for a magnetic media structure made with the prior art original plasma magnetron-sputtering cathode. Similarly, the data range labeled “Modified” is MrT data for a magnetic media structure made with the new magnetron-sputtering cathodes of FIG. 2. The data of FIG. 6B shows that the spread in MrT values decreases significantly when the “Original” cathodes are changed out for the “Modified” cathodes. This improved MrT uniformity is a direct result of the improved magnetron-sputtering cathode having magnetic flux shown in FIG. 4B, which compensates for non-uniformities resulting from gas flowing from the top of the substrate to the bottom of the substrate.

It will also be recognized by those skilled in the art that, while the invention has been described above in terms of preferred embodiments, it is not limited thereto. Various features and aspects of the above-described invention may be used individually or jointly. Further, although the invention has been described in the context of its implementation in a particular environment and for particular applications, those skilled in the art will recognize that its usefulness is not limited thereto and that the present invention can be utilized in any number of environments and implementations.

What is claimed is:

1. A magnetron-sputtering cathode, comprising:
a first plurality of magnets positioned and spaced apart in a substantially outer circular pattern such that gaps of at least two different sizes are formed between each magnet; and
a second plurality of magnets positioned and spaced apart in a substantially inner circular pattern, wherein said inner circular pattern is located inside of said outer circular pattern.

2. The magnetron-sputtering cathode of claim 1, wherein said substantially outer circular pattern further includes a top pattern and a bottom pattern.

3. The magnetron-sputtering cathode of claim 1, wherein said gaps in said top pattern are of a different size than said gaps in said bottom pattern.

4. The magnetron-sputtering cathode of claim 3, wherein said gaps in said bottom pattern are larger than said gaps in said top pattern.

5. The magnetron-sputtering cathode of claim 1 wherein said outer circular pattern and inner circular pattern are concentrically located with respect to each other.

6. A sputtering apparatus, comprising:
a chamber;
a gas inlet for supplying gas used in sputtering;
a vacuum pump connected with said vacuum chamber;
a magnetron-sputtering cathode positioned within said chamber;
wherein said magnetron-sputtering cathode, comprises
a first plurality of magnets positioned and spaced apart in a substantially outer circular pattern such that gaps of at least two different sizes are formed between each magnet, wherein said substantially outer circular pattern further includes a top pattern and a bottom pattern; and
a second plurality of magnets positioned and spaced apart in a substantially inner circular pattern, wherein said inner circular pattern is located inside of said outer circular pattern.

7. The apparatus of claim 6, wherein said magnetron-sputtering cathode is positioned so that said bottom pattern is oriented towards said vacuum pump.

8. The apparatus of claim 6, wherein said gaps in said top pattern are of a different size than said gaps in said bottom pattern.

9. The magnetron-sputtering cathode of claim 6, wherein said gaps in said bottom pattern are larger than said gaps in said top.

10. The apparatus of claim 6 further including a second magnetron-sputtering cathode substantially similar to said magnetron-sputtering cathode.

11. The apparatus of claim 10 wherein said second magnetron-sputtering cathode is positioned opposite to and symmetric to said magnetron-sputtering cathode so that both sides of a substrate can be simultaneously sputtered.

12. A method of producing uniform magnetic films, comprising:
providing a substrate into a sputtering apparatus;
injecting a gas to enter into said sputtering apparatus,
passing said gas over said substrate and over a magnetron-sputtering cathode, wherein said magnetron-sputtering cathode, comprises:
a first plurality of magnets positioned and spaced apart in a substantially outer circular pattern such that gaps of at least two different sizes are formed between each magnet, wherein said substantially outer circular pattern further includes a top pattern and a bottom pattern; and
a second plurality of magnets positioned and spaced apart in a substantially inner circular pattern, wherein said inner circular pattern is located inside of said outer circular pattern; and
pumping out said gas into a vacuum pump disposed within said sputtering apparatus.

13. The method of claim 12, wherein said substrate is substantially circular.

14. The method of claim 12, wherein said gas is a noble gas.

15. The method of claim 12, wherein said substantially outer circular pattern further includes a top pattern and a bottom pattern.

16. The method of claim 15, wherein said gaps in said top have a size that is different than said gaps in said bottom.

17. The method of claim 16, wherein said gaps in said bottom are larger than said gaps in said top.

18. The method of claim 17, wherein said magnetron-sputtering cathode is positioned so that said bottom pattern is oriented towards said vacuum pump.

19. The method of claim 18 further including passing said gas over a second magnetron-sputtering cathode substantially similar to said sputtering magnetron-sputtering cathode.

20. The apparatus of claim 19 wherein said second magnetron-sputtering cathode is positioned opposite to and symmetric to said magnetron-sputtering cathode so that both sides of a substrate can be simultaneously sputtered.
